(19) United States
(12) Patent Application Publication
(10) Pub. No.: US 2026/0262278 A1
(43) Pub. Date: Sep. 3, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Kyungpil NAM, Himeji Hyogo (JP); Shunsuke ASABA, Himeji Hyogo (JP); Hiroshi KONO, Himeji Hyogo (JP); Yujiro HARA, Himeji Hyogo (JP)

(21) Appl. No.: 19/264,383

(22) Filed: Jul. 9, 2025

(30) Foreign Application Priority Data
Feb. 28, 2025 (JP) 2025-031904

(51) Int. Cl. H10D 84/00; H01L 23/00; H10D 8/60; H10D 30/63; H10D 62/10

(52) U.S. Cl. CPC H10D 84/101; H10D 8/60; H10D 30/63; H10D 62/126; H10W 72/531

(57) ABSTRACT

According to one embodiment, a semiconductor device includes a first electrode, a second electrode, and a semiconductor member provided between the first electrode and the second electrode. The semiconductor member includes a diode region including a first region and a second region, and a transistor region. The first region and the second region extend along a first direction. A first position of the first region in a second direction is different from a second position of the second region in the second direction. The second direction crosses the first direction. The semiconductor member is between the first electrode and the second electrode in a third direction crossing a plane including the first direction and the second direction. At least a part of the transistor region is provided around the diode region in the plane.

### CROSS-REFERENCE TO RELATED APPLICATIONS

This application is based upon and claims the benefit of priority from Japanese Patent Application No. 2025-031904, filed on Feb. 28, 2025; the entire contents of which are incorporated herein by reference.

### FIELD

Embodiments described herein relate generally to a semiconductor device.

### BACKGROUND

For example, stable characteristics are desired in semiconductor devices.

### BRIEF DESCRIPTION OF THE DRAWINGS

FIG. 1 is a schematic plan view illustrating a semiconductor device according to a first embodiment;

FIG. 2 is a schematic cross-sectional view illustrating a part of the semiconductor device according to the first embodiment;

FIG. 3 is a schematic cross-sectional view illustrating a part of the semiconductor device according to the first embodiment;

FIG. 4 is a schematic cross-sectional view illustrating a part of the semiconductor device according to the first embodiment;

FIG. 5 is a schematic plan view illustrating a semiconductor device according to a second embodiment; and

FIG. 6 is a schematic plan view illustrating the characteristics of the semiconductor device according to the second embodiment.

### DETAILED DESCRIPTION

According to one embodiment, a semiconductor device includes a first electrode, a second electrode, and a semiconductor member provided between the first electrode and the second electrode. The semiconductor member includes a diode region including a first region and a second region, and a transistor region. The first region and the second region extend along a first direction. A first position of the first region in a second direction is different from a second position of the second region in the second direction. The second direction crosses the first direction. The semiconductor member is between the first electrode and the second electrode in a third direction crossing a plane including the first direction and the second direction. At least a part of the transistor region is provided around the diode region in the plane.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

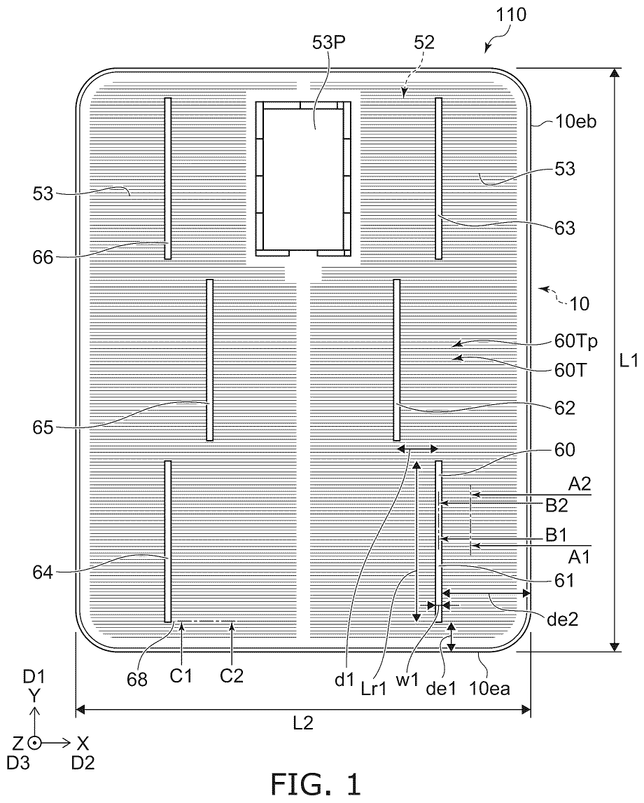

FIG. 1 is a schematic plan view illustrating a semiconductor device according to a first embodiment.

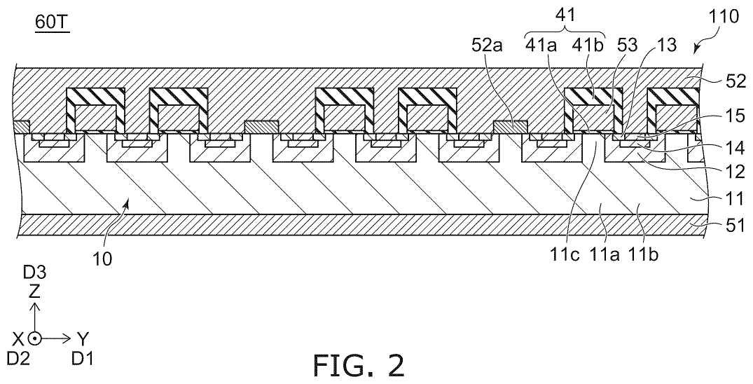

FIGS. 2 to 4 are schematic cross-sectional views illustrating a part of the semiconductor device according to the first embodiment.

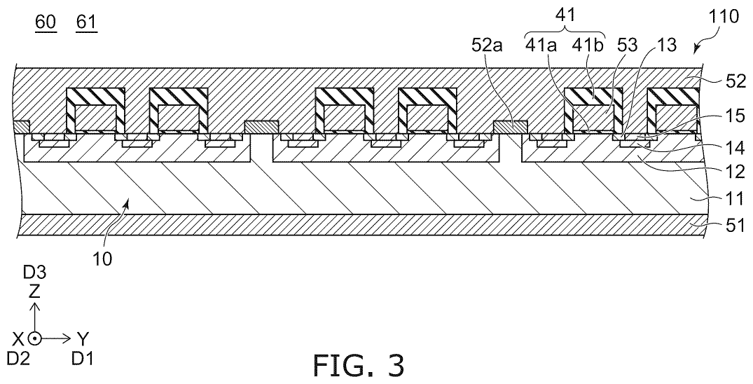

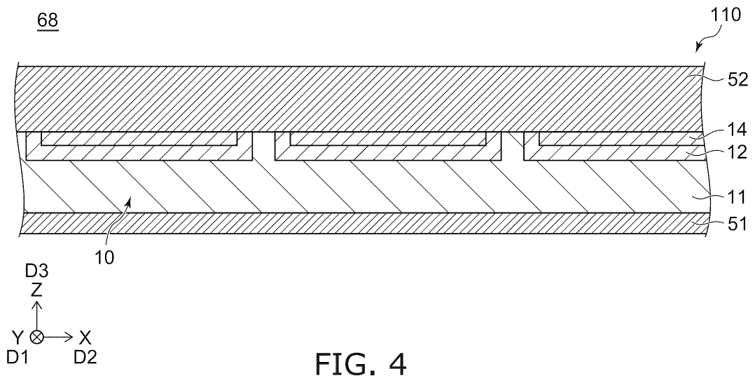

FIG. 2 is a cross-sectional view taken along the line A1-A2 in FIG. 1. FIG. 3 is a cross-sectional view taken along the line B1-B2 in FIG. 1. FIG. 4 is a cross-sectional view taken along the line C1-C2 in FIG. 1.

As shown in FIGS. 1 to 4, a semiconductor device 110 according to the embodiment includes a first electrode 51, a second electrode 52, and a semiconductor member 10. The semiconductor device 110 may further include a third electrode 53 and a first insulating member 41.

The semiconductor member 10 is provided between the first electrode 51 and the second electrode 52.

The semiconductor member 10 includes a diode region 60 and a transistor region 60T. The transistor region 60T is, for example, a MOS (Metal Oxide Semiconductor) region.

As shown in FIG. 1, the diode region 60 includes a plurality of regions. For example, the diode region 60 includes a first region 61 and a second region 62. The first region 61 and the second region 62 extend along a first direction D1. A first position of the first region 61 in a second direction D2 is different from a second position of the second region 62 in the second direction D2. The second direction D2 crosses the first direction D1.

The first direction D1 is defined as a Y-axis direction. A direction perpendicular to the Y-axis direction is defined as an X-axis direction. A direction perpendicular to the Y-axis direction and the X-axis direction is defined as a Z-axis direction. The second direction D2 is, for example, the X-axis direction.

A third direction D3 from the first electrode 51 to the second electrode 52 crosses a plane including the first direction D1 and the second direction D2. The third direction D3 may be, for example, the Z-axis direction. The plane including the first direction D1 and the second direction D2 corresponds to, for example, the X-Y plane.

The semiconductor member 10 is between the first electrode 51 and the second electrode 52 in the third direction D3. At least a part of the transistor region 60T is provided around the diode region 60 in this plane (the X-Y plane). For example, at least a part of the transistor region 60T is around the first region 61 and the second region 62 in the X-Y plane.

As shown in FIG. 2, the first insulating member 41 includes a first insulating region 41a. The first insulating region 41a is between the semiconductor member 10 and the third electrode 53. The first insulating member 41 may further include a second insulating region 41b. The second insulating region 41b is between the third electrode 53 and the second electrode 52.

Current flowing between the first electrode 51 and the second electrode 52 is controlled by a potential of the third electrode 53. The potential of the third electrode 53 may be a potential based on a potential of the second electrode 52. The first electrode 51 functions as, for example, a drain electrode. The second electrode 52 functions as, for example, a source electrode. The third electrode 53 functions as, for example, a gate electrode. The semiconductor device 110 is, for example, a MOS transistor.

The diode region 60 has, for example, a function of spreading a surge current. By providing the diode region 60, more stable operation can be possible.

Since the surge current flows through the diode region 60, the temperature is likely to rise in the diode region 60 and its surroundings. This may cause damage to various wiring materials (and connection members).

As described above, in the embodiment, the positions of the plurality of regions (such as the first region 61 and the second region 62) of the diode region 60 in the second direction D2 are shifted. For example, the second region 62 is discontinuous with the first region 61. This allows heat to spread easily in the diode region 60 and its surroundings. Thereby, local rise of the temperature is suppressed. Excessive temperature rises are prevented. For example, damage to wiring materials and the like is suppressed.

For example, there is a reference example in which the second region 62 is continuous with the first region 61 and does not shift in position in the second direction D2. In the reference example, a long, continuous diode region 60 is provided. In the reference example, excessive heat is likely to accumulate in the central part of the long, continuous diode region 60. Localized high temperatures are likely to occur. This easily results in a damage in the wiring materials and the like.

In contrast, in the embodiment, the diode region 60 is divided into a plurality of regions (such as the first region 61 and the second region 62). The positions of the plurality of regions are shifted in the second direction D2. The second region 62 is discontinuous with the first region 61. This spreads heat and suppresses the excessive rise in temperature. Damage to wiring materials and the like is suppressed. According to the embodiment, a semiconductor device capable of obtaining stable characteristics can be provided.

For example, an area of the PN region of the diode region 60 per unit area is larger than an area of the PN region of the transistor region 60T per unit area. A contact resistance per unit area between the source electrode (second electrode 52) and the p region (e.g., the second semiconductor region 12) in the diode region 60 is smaller than a contact resistance per unit area between the source electrode (second electrode 52) and the body region (e.g., the second semiconductor region 12) in the transistor region 60T. For example, the current flowing through the PN junction diode in the diode region 60 is greater than the current flowing through the PN junction diode in the transistor region 60T.

The resistance in the diode region 60 is lower than the resistance of the diode (body diode) in the MOSFET portion (transistor region 60T).

For example, when a large current such as a surge is applied, a large current can flow in the diode region 60. The diode region 60 has the effect of concentrating the surge current.

When a surge current is applied, the diode region 60 is more susceptible to conductivity modulation than the transistor region 60T, and the effect of the conductivity modulation is also stronger. The region in the diode region 60 where the conductivity is modulated becomes, for example, the “starting point.” Carriers generated by the conductivity modulation spread to the neighboring cell, further increasing the amount of current. When the amount of current increases, the temperature of the diode region 60 increases, and the forward voltage Vf in the diode region 60 decreases. This allows positive feedback to be obtained. For example, a large current flows through a PN diode, causing carrier propagation to the neighboring transistor region 60T and heat propagation. This promotes the modulation of the conductivity.

For example, the surge current is concentrated in the diode region 60 (promoting the modulation of the conductivity), and the large current and heat are dispersed to the neighboring cell or diode region 60. This improves the surge current.

For example, the number of diode regions 60 may be the same as the number of bonding wires provided in the source plane. For example, if the number of bonding wires provided in the source plane is three, the number of diode regions 60 is preferably three. The plurality of diode regions 60 may be aligned along the long direction of the chip.

As already explained, if the plurality of diode regions 60 are not shifted, localized heat will be generated in the areas between the plurality of diode regions 60, damaging the cell portion. The heat becomes a cause of deviation in surge resistance.

As shown in FIG. 1, a length of the semiconductor member 10 along the first direction D1 is defined as a first semiconductor member length L1. A length of the semiconductor member 10 along the second direction D2 is defined as a second semiconductor member length L2. In the embodiment, the first semiconductor member length L1 may be equal to or more than the second semiconductor member length L2. For example, each of the plurality of diode regions 60 extends along the long direction of the semiconductor member 10. This makes it easier to spread, for example, a surge current.

As shown in FIG. 1, in this example, the first region 61 is between two regions of the transistor region 60T in the first direction D1. The second region 62 is between the other two regions of the transistor region 60T in the first direction D1.

The first region 61 is between two regions of the transistor region 60T in the second direction D2. The second region 62 is between the other two regions of the transistor region 60T in the second direction D2.

As shown in FIG. 1, the diode region 60 may further include a third region 63. A part of the transistor region 60T is around the third region 63 in the X-Y plane. The third region 63 extends along the first direction D1. A third position of the third region 63 in the second direction D2 is different from the second position.

In this example, the position of the second region 62 in the first direction D1 is between the position of the first region 61 in the first direction D1 and the position of the third region 63 in the first direction D1. The transistor region 60T includes a first portion 60Tp. For example, at least a part of the first portion 60Tp may be provided between the first region 61 and the third region 63 in the first direction D1. A direction from the second region 62 to the first portion 60Tp may be along the second direction D2.

As shown in FIG. 1, a distance along the second direction D2 between the first position in the second direction D2 of the first region 61 and the second position in the second direction D2 of the second region 62 is defined as a first distance d1. The first distance d1 corresponds to the shift distance. A length (width) of the first region 61 along the second direction D2 is defined as a first region width w1. The first distance d1 is longer than the first region width w1. For example, the first distance d1 may be 5 times or more the first region width w1.

In one example, the first distance d1 may be, for example, not less than 200 μm and not more than 800 μm. The first region width w1 may be, for example, not less than 4 μm and not more than 100 μm.

For example, a length of the first region 61 along the first direction D1 is defined as a first region length Lr1. The first region length Lr1 may be 5 times or more the first region width w1 along the second direction D2 of the first region 61. In one example, the first region length Lr1 may be, for example, not less than 1000 μm and not more than 1500 μm.

As shown in FIG. 1, the semiconductor member 10 includes a first end 10ea in the first direction D1 and a second end 10eb in the second direction D2. The first end 10ea is closest to the first region 61 in the first direction D1 among the plurality of end portions included in the semiconductor member 10. The second end 10eb is closest to the first region 61 in the second direction D2 among the plurality of end portions included in the semiconductor member 10. A distance in the second direction D2 between the first region 61 and the second end 10eb is defined as a second end distance de2. A distance in the first direction D1 between the first region 61 and the first end 10ea is defined as a first end distance de1. For example, the second end distance de2 may be longer than the first end distance de1. The first region 61 is farther away from the second end 10eb in the second direction D2. This makes it possible to more effectively suppress local temperature rise.

As shown in FIG. 1, the diode region 60 may include other plurality of regions (such as a fourth region 64, a fifth region 65, and a sixth region 66). The configurations of the first region 61, the second region 62, and the third region 63 already described may be applied to these regions, respectively.

In this example, a plurality of third electrodes 53 are provided. The third electrodes 53 extend along the second direction D2. The third electrodes 53 are aligned along the first direction D1. The third electrodes 53 are electrically connected to a third electrode pad 53P.

FIG. 2 illustrates a cross section of the transistor region 60T. The semiconductor member 10 includes a first semiconductor region 11 of a first conductivity type, a second semiconductor region 12 of a second conductivity type, and a third semiconductor region 13 of the first conductivity type. The first conductivity type is one of n-type and p-type. The second conductivity type is the other of n-type and p-type. In the following, the first conductivity type is n-type, and the second conductivity type is p-type.

As shown in FIG. 2, the first semiconductor region 11 may include a first partial region 11a, a second partial region 11b, and a third partial region 11c. A direction from the first partial region 11a to the second partial region 11b crosses the third direction D3. In this example, the direction from the first partial region 11a to the second partial region 11b is along the first direction D1.

The second partial region 11b is between the first electrode 51 and the second semiconductor region 12 in the third direction D3. At least a part of the third semiconductor region 13 is between the second semiconductor region 12 and the second electrode 52. The third semiconductor region 13 is electrically connected to the second electrode 52.

In the transistor region 60T, the third partial region 11c is between the first partial region 11a and the third electrode 53 in the third direction D3. In the transistor region 60T, a direction from the third partial region 11c to the second semiconductor region 12 crosses the third direction D3. In this example, a direction from the third partial region 11c to the second semiconductor region 12 is along the first direction D1.

A third impurity concentration of the first conductivity type in the third semiconductor region 13 is higher than a first impurity concentration of the first conductivity type in the first semiconductor region 11.

As shown in FIG. 2, the semiconductor member 10 may include a fourth semiconductor region 14 of the second conductivity type. The fourth semiconductor region 14 is between the second semiconductor region 12 and the second electrode 52. A fourth impurity concentration of the second conductivity type in the fourth semiconductor region 14 is higher than the second impurity concentration of the second conductivity type in the second semiconductor region 12.

As shown in FIG. 2, the semiconductor member 10 may include a fifth semiconductor region 15 of the second conductivity type. The fifth semiconductor region 15 is between the fourth semiconductor region 14 and the second electrode 52. A fifth impurity concentration of the second conductivity type in the fifth semiconductor region 15 is higher than the fourth impurity concentration of the second conductivity type in the fourth semiconductor region 14. The fifth semiconductor region 15 may include, for example, a metal silicide. The fifth semiconductor region 15 may include, for example, at least one selected from the group consisting of titanium silicide and nickel silicide.

The semiconductor device 110 may further include a first electrode portion 52a. The first electrode portion 52a is provided between the first semiconductor region 11 and the second electrode 52. For example, the first electrode portion 52a is in contact with the first semiconductor region 11. A Schottky diode may be formed in the portion including the first electrode portion 52a. The first electrode portion 52a may include, for example, at least one selected from the group consisting of Ti and Al.

FIG. 3 illustrates a cross section of the diode region 60. In the diode region 60, the third partial region 11c is not provided between the first partial region 11a and the third electrode 53. In the diode region 60, a part of the second semiconductor region 12 is provided between the first partial region 11a and the third electrode 53. A PN junction is formed in the diode region 60.

As shown in FIG. 1, the diode region 60 may include a cross direction region 68. The cross direction region 68 extends along the second direction D2.

FIG. 4 illustrates a cross section of the cross direction region 68. As shown in FIG. 4, a PN junction is formed by the first semiconductor region 11 and the second semiconductor region 12.

### Second Embodiment

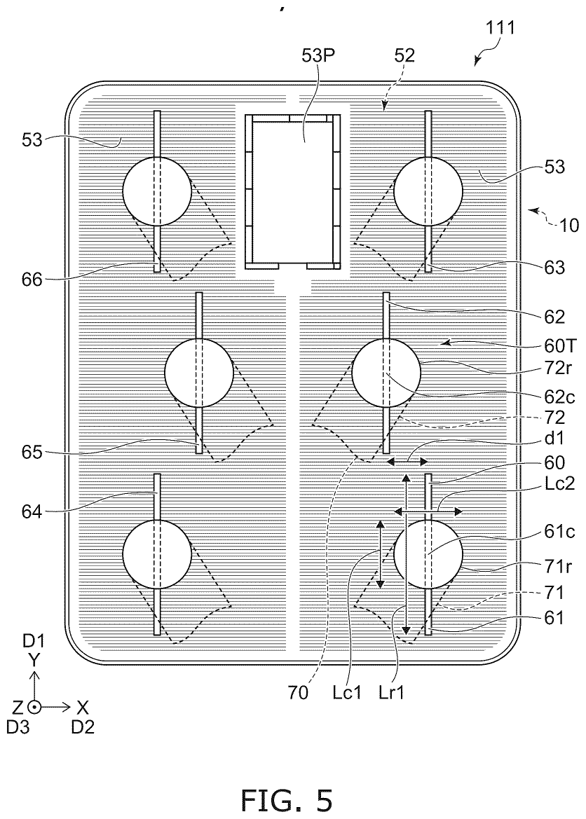

FIG. 5 is a schematic plan view illustrating a semiconductor device according to a second embodiment.

As shown in FIG. 5, a semiconductor device 111 according to the embodiment includes a connection member 70. The configuration of the semiconductor device 111 except for this may be the same as the configuration of the semiconductor device 110.

The connection member 70 is, for example, a bonding wire. The connection member 70 may include a first connection member 71 and a second connection member 72. The first connection member 71 and the second connection member 72 are electrically connected to the second electrode 52.

The first connection member 71 includes a first connection region 71r that is connected to the second electrode 52. At least a part of the first connection region 71r overlaps the first region 61 in the third direction D3. The second connection member 72 includes a second connection region 72r that is connected to the second electrode 52. At least a part of the second connection region 72r overlaps the second region 62 in the third direction D3. By these connection regions overlapping the diode region 60, for example, a surge current can spread efficiently.

For example, a large surge current flows through the diode region 60 compared to the transistor region 60T, so heat is generated in the diode region 60. The current flowing through the bonding wire also heats up the connection part of the bonding wire. The heat generated in the diode region 60 interacts with the heat generated in the connection part of the bonding wire, further increasing the heat generation. These lead to a decrease in the forward voltage Vf of the diode region 60 and enhanced conductivity modulation.

In the embodiment, the surge current and heat generated by wire bonding can be immediately propagated to the diode region 60. For example, a large current flowing through the diode region 60 causes carrier propagation and heat propagation to the adjacent MOSFET region. Good propagation is obtained. Good heat diffusion is obtained.

As already explained, a Schottky diode (SBD) may be formed in the portion including the first electrode portion 52a. In the embodiment, by providing the diode region 60, the transistor region 60T, and the SBD region, a better IFSM (Peak Surge Forward Current) is obtained compared to the case where the transistor region 60T and the SBD region are provided.

The first region 61 may include a first center 61c in the first direction D1. At least a part of the first connection region 71r may overlap the first center 61c in the third direction D3. For example, heat concentration is suppressed. The second region 62 may include a second center 62c in the first direction D1. At least a part of the second connection region 72r may overlap the second center 62c in the third direction D3. For example, heat concentration is suppressed.

As shown in FIG. 5, a length (width) of the first connection region 71r in the second direction D2 is defined as a first connection region width Lc2. As already explained, the distance (shift distance) along the second direction D2 between the first position of the first region 61 in the second direction D2 and the second position of the second region 62 in the second direction D2 is defined as the first distance d1. The first connection region width Lc2 may be 1/10 or more of the first distance d1. The first connection region width Lc2 may be 5 times or less than the first distance d1.

A length of the first connection region 71r in the first direction D1 is defined as a first connection region length Lc1. As already explained, the length of the first region 61 along the first direction D1 is defined as the first region length Lr1. In the embodiment, the first region length Lr1 may be 4 times or less than the first connection region length Lc1. The first region length Lr1 may be equal to or more than one time the first connection region length Lc1.

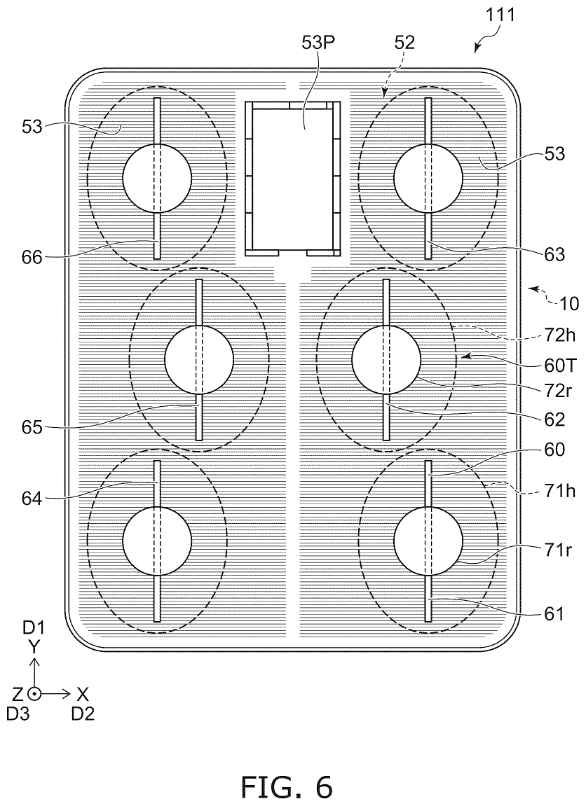

FIG. 6 is a schematic plan view illustrating the characteristics of the semiconductor device according to the second embodiment.

As shown in FIG. 6, in the semiconductor device 111, a first high temperature region 71h exists corresponding to the first connection region 71r. The length of the first high temperature region 71h in the second direction D2 is shorter than the length of the first high temperature region 71h in the first direction D1. A second high temperature region 72h exists corresponding to the second connection region 72r. The length of the second high temperature region 72h in the second direction D2 is shorter than the length of the second high temperature region 72h in the first direction D1. The second high temperature region 72h is not substantially continuous with the first high temperature region 71h. The temperature rise is suppressed.

The semiconductor member 10 may include SiC or Si. The semiconductor member 10 may include, for example, at least one selected from the group consisting of 4H—SiC, 6H—SiC, and 3C—SiC. When the semiconductor member 10 includes SiC, the impurity of the first conductivity type includes, for example, at least one selected from the group consisting of N, P, and As. When the semiconductor member 10 includes SiC, the impurity of the second conductivity type includes, for example, at least one selected from the group consisting of B, Al, and Ga. The semiconductor member 10 may include, for example, a compound semiconductor including Ga.

At least one of the first electrode 51 and the second electrode 52 may include at least one selected from the group consisting of Al, Cu, Ti, Ni, Ag, and Au. At least one of the first electrode 51 and the second electrode 52 may include at least one selected from the group consisting of titanium silicide and nickel silicide. The third electrode 53 may include, for example, conductive polysilicon.

In the embodiment, information regarding the length and thickness is obtained by observation with an electron microscope, etc. Information regarding the composition of the material is obtained by SIMS (Secondary Ion Mass Spectrometry) or EDX (Energy dispersive X-ray spectroscopy), etc.

According to the embodiment, a semiconductor device capable of obtaining stable characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode; and
a semiconductor member provided between the first electrode and the second electrode,
the semiconductor member including:
a diode region including a first region and a second region; and
a transistor region,
the first region and the second region extending along a first direction,
a first position of the first region in a second direction being different from a second position of the second region in the second direction,
the second direction crossing the first direction,
the semiconductor member being between the first electrode and the second electrode in a third direction crossing a plane including the first direction and the second direction, and
at least a part of the transistor region being provided around the diode region in the plane.

2. The semiconductor device according to claim 1, wherein
the second region is discontinuous with the first region.

3. The semiconductor device according to claim 1, wherein
a first semiconductor member length along the first direction of the semiconductor member is equal to or more than a second semiconductor member length along the second direction of the semiconductor member.

4. The semiconductor device according to claim 1, further comprising:
a third electrode; and
a first insulating member including a first insulating region,
the first insulating region being between the semiconductor member and the third electrode.

5. The semiconductor device according to claim 4, wherein
the semiconductor member includes a first semiconductor region of a first conductivity type, a second semiconductor region of a second conductivity type, and a third semiconductor region of the first conductivity type,
the first semiconductor region includes a first partial region, a second partial region, and a third partial region,
a direction from the first partial region to the second partial region crosses the third direction,
the second partial region is between the first electrode and the second semiconductor region in the third direction,
at least a part of the third semiconductor region is between the second semiconductor region and the second electrode,
the third semiconductor region is electrically connected to the second electrode,
in the transistor region, the third partial region is between the first partial region and the third electrode in the third direction, and
in the transistor region, a direction from the third partial region to the second semiconductor region crosses the third direction.

6. The semiconductor device according to claim 5, wherein
in the diode region, the third partial region is not provided between the first partial region and the third electrode, and
in the diode region, a part of the second semiconductor region is provided between the first partial region and the third electrode.

7. The semiconductor device according to claim 5, wherein
the third electrode extends along the second direction.

8. The semiconductor device according to claim 1, wherein
the first region is between two regions of the transistor region in the first direction, and
the second region is between two other regions of the transistor region in the first direction.

9. The semiconductor device according to claim 1, wherein
the diode region further includes a third region,
a part of the transistor region is provided around the third region in the plane,
the third region extends along the first direction, and
a third position of the third region in the second direction is different from the second position.

10. The semiconductor device according to claim 9, wherein
a position of the second region in the first direction is between a position of the first region in the first direction and a position of the third region in the first direction.

11. The semiconductor device according to claim 10, wherein
the transistor region includes a first portion,
at least a part of the first portion is between the first region and the third region in the first direction, and
a direction from the second region to the first portion is along the second direction.

12. The semiconductor device according to claim 1, wherein
a first distance along the second direction between the first position and the second position is longer than a first region width along the second direction of the first region.

13. The semiconductor device according to claim 12, wherein
the first distance is at least 5 times the first region width.

14. The semiconductor device according to claim 1, wherein
a first region length along the first direction of the first region is at least 5 times a first region width along the second direction of the first region.

15. The semiconductor device according to claim 1, wherein
the semiconductor member includes:
a first end in the first direction, and
a second end in the second direction, and
a second end distance in the second direction between the first region and the second end is longer than a first end distance in the first direction between the first region and the first end.

16. The semiconductor device according to claim 1, further comprising:
a first connection member; and
a second connection member,
the first connection member and the second connection member being electrically connected to the second electrode,
the first connection member includes a first connection region connected to the second electrode,
at least a part of the first connection region overlaps the first region in the third direction,
the second connection member includes a second connection region connected to the second electrode, and
at least a part of the second connection region overlaps the second region in the third direction.

17. The semiconductor device according to claim 16, wherein
the first region includes a first center in the first direction,
at least a part of the first connection region overlaps the first center in the third direction,
the second region includes a second center in the first direction, and
at least a part of the second connection region overlaps the second center in the third direction.

18. The semiconductor device according to claim 16, wherein
a first distance along the second direction between the first position and the second position is equal to or more than 1/10 of a first connection region width in the second direction of the first connection region.

19. The semiconductor device according to claim 16, wherein
a first connection region length in the first direction of the first connection region is 0.8 times or less a first region length along the first direction of the first region.

20. The semiconductor device according to claim 1, wherein
the diode region includes a cross direction region, and
the cross direction region extends along the second direction.
